(19) United States
(12) Patent Application Publication
(10) Pub. No.: US 2025/0168965 A1
(43) Pub. Date: May 22, 2025

(54) CIRCUIT BOARD, AND ELECTRONIC COMPONENT PACKAGE INCLUDING THE SAME

(71) Applicant: SAMSUNG ELECTRO-MECHANICS CO., LTD., Suwon-si (KR)

(72) Inventors: Gyumook Kim, Suwon-si (KR); Sanghoon Kim, Suwon-si (KR); Young Kuk Ko, Suwon-si (KR)

(73) Assignee: SAMSUNG ELECTRO-MECHANICS CO., LTD., Suwon-si (KR)

(21) Appl. No.: 18/896,111

(22) Filed: Sep. 25, 2024

(30) Foreign Application Priority Data
Nov. 21, 2023 (KR) 10-2023-0161949
Jul. 16, 2024 (KR) 10-2024-0093965

(51) Int. Cl. H05K 1/02; H05K 1/14; H05K 1/18

(52) U.S. Cl. CPC H05K 1/0209; H05K 1/0206; H05K 1/0298; H05K 1/144; H05K 1/183; H05K 2201/042; H05K 2201/09827; H05K 2201/10462

(57) ABSTRACT

A circuit board includes: a first insulating layer having first and second surfaces opposing each other, and having a cavity recessed from the first surface; a first heat dissipation pattern disposed on the second surface of the first insulating layer; and a heat dissipation part connected to the first heat dissipation pattern, and protruding into the cavity by penetrating through the first insulating layer.

### CROSS-REFERENCE TO RELATED APPLICATION

This application claims priority to and the benefit of Korean Patent Application Nos. 10-2023-0161949 filed on Nov. 21, 2023 and 10-2024-0093965 filed on Jul. 16, 2024 in the Korean Intellectual Property Office, the entire contents of which are incorporated herein by reference.

### TECHNICAL FIELD

The present disclosure relates to a circuit board, and an electronic component package including the same.

### BACKGROUND

A circuit board may have a circuit pattern formed with a conductive material, such as copper, on an insulating material. As an electronic device in an information technology (IT) field, including a mobile phone has become smaller, a method has been proposed to form a cavity in the circuit board and accommodate an electronic component such as an integrated circuit (IC), an active element, or a passive element in the cavity.

The electronic component such as an application processor (AP) or a dynamic random access memory (DRAM), accommodated in the cavity of the circuit board, has continuously evolved performance, thus causing a lot of heat in the electronic component in a process of quickly transmitting a larger amount of data.

Accordingly, there is a need to develop a circuit board with a heat dissipation feature for the electronic component to demonstrate more stable performance and an electronic component package including the same.

### SUMMARY

The present disclosure attempts to provide a circuit board which may efficiently absorb and dissipate heat occurring in an electronic component while securing a mounting space of the electronic component, and an electronic component package including the same.

The present disclosure also attempts to provide a circuit board which may use a structure having a heat dissipation effect for an electronic component of various thicknesses, and efficiently absorb and dissipate heat occurring in the electronic component even when a circuit pattern layer has a complex design, and an electronic component package including the same.

However, problems to be solved by embodiments of the present disclosure are not limited to the above-mentioned problems and may be variously expanded in a range of the spirit of the present disclosure included in the embodiments.

According to an embodiment, a circuit board includes: a first insulating layer having first and second surfaces opposing each other, and having a cavity recessed from the first surface; a first heat dissipation pattern disposed on the second surface of the first insulating layer; and a heat dissipation part connected to the first heat dissipation pattern, and protruding into the cavity by penetrating through the first insulating layer.

The circuit board may further include a second insulating layer disposed on the second surface in a first direction to cover the first heat dissipation pattern and at least one circuit pattern layer. The first insulating layer may include an upper region overlapping the cavity in the first direction and a side region overlapping the cavity in a second direction perpendicular to the first direction, and the heat dissipation part may protrude from the upper region.

The heat dissipation part may include a first part buried in the first insulating layer, and a second part extending from the first part and protruding from the upper region.

The first insulating layer may have a groove in the upper region where the second part is disposed, and the groove may surround the second part.

The first circuit pattern layer may further include a first pattern layer including the first heat dissipation pattern and a first circuit pattern layer disposed around the first heat dissipation pattern, wherein the heat dissipation pattern may be connected to at least one other pattern layer.

The first insulating layer may further include a second heat dissipation pattern disposed on the first surface of the first insulating layer, wherein the first heat dissipation pattern may be connected to the second heat dissipation pattern.

The circuit board may further include: a second insulating layer disposed on the second surface in a first direction to cover at least one circuit pattern layer including the first pattern layer; and a third heat dissipation pattern disposed on a third surface of the second insulating layer that opposes the second surface of the first insulating layer. The first heat dissipation pattern may be connected to the third heat dissipation pattern.

The heat dissipation part may extend to be parallel to an edge of the cavity.

The plurality of heat dissipation parts may be provided, and the plurality of heat dissipation parts may include portions aligned with each other in one direction.

The plurality of heat dissipation parts may be provided, and the plurality of heat dissipation parts may be spaced apart from each other.

The heat dissipation part may include copper.

According to another embodiment, an electronic component package includes: a first circuit board having a cavity in one surface; a second circuit board connected to the first circuit board; and an electronic component mounted on one surface of the second circuit board, and accommodated in the cavity, wherein the first the circuit board includes a first insulating layer having first and second surfaces opposing each other, and having the cavity recessed from the first surface, a first heat dissipation pattern disposed on the second surface of the first insulating layer, and a heat dissipation part connected to the first heat dissipation pattern, and protruding into the cavity by penetrating through the first insulating layer.

The package may further include a second insulating layer disposed on the second surface in a first direction to cover the first heat dissipation pattern and at least one circuit pattern layer including the first circuit pattern layer. The first insulating layer may include an upper region overlapping the cavity in the first direction and a side region overlapping the cavity in a second direction perpendicular to the first direction, and the heat dissipation part may protrude from the upper region.

The heat dissipation part may include a first part buried in the first insulating layer, and a second part extending from the first part and protruding from the upper region.

The first insulating layer may have a groove in the upper region where the second part is disposed, and a width of the groove may be greater than a width of the second part.

The package may further include a first pattern layer including the first heat dissipation pattern and a first circuit pattern layer disposed around the first heat dissipation pattern, and the first heat dissipation pattern may be connected to at least one other pattern layer.

The first insulating layer may further include a second heat dissipation pattern disposed on the first surface of the first insulating layer wherein the first heat dissipation pattern may be connected to the second heat dissipation pattern.

The package may further include: a second insulating layer disposed on the second surface in a first direction to cover at least one pattern layer including the first pattern layer; and a third heat dissipation pattern disposed on a third surface of the second insulating layer that opposes the second surface of the first insulating layer, wherein the first heat dissipation pattern is connected to the third heat dissipation pattern.

The heat dissipation part may extend to be parallel to an edge of the cavity.

The plurality of heat dissipation parts may be provided, and the plurality of heat dissipation parts may include portions aligned with each other in one direction.

As set forth above, the present disclosure may provide the circuit board which may efficiently absorb and dissipate heat occurring in the electronic component while securing the mounting space of the electronic component, and the electronic component package including the same.

The present disclosure may also provide a circuit board which may use the structure having the heat dissipation effect for the electronic component of the various thicknesses, and efficiently absorb and dissipate heat occurring in the electronic component even when the circuit pattern layer has the complex design, and the electronic component package including the same.

### BRIEF DESCRIPTION OF THE DRAWINGS

FIG. 1 is a cross-sectional view of a circuit board according to an embodiment.

FIG. 2 is a plan view schematically showing one surface of the circuit board of FIG. 1.

FIGS. 3 to 15 are cross-sectional views showing a method of manufacturing the circuit board according to an embodiment.

FIG. 16 is a cross-sectional view schematically showing an electronic component package according to another embodiment.

FIG. 17 is a cross-sectional view of a circuit board in another example.

FIG. 18 is a plan view schematically showing one surface of a circuit board in still another example.

### DETAILED DESCRIPTION OF THE EMBODIMENT

Hereinafter, embodiments of the present disclosure are described in detail with reference to the accompanying drawings for those skilled in the art to which the present disclosure pertains to easily practice the present disclosure. A portion unrelated to the description is omitted in order to obviously describe the present disclosure, and the same or similar components are denoted by the same reference numeral throughout the specification. In addition, some components shown in the accompanying drawings are exaggerated, omitted or schematically shown, and the size of each component does not exactly reflect its real size.

It is to be understood that the accompanying drawings are provided only to allow the embodiments of the present disclosure to be easily understood, and the spirit of the present disclosure is not limited by the accompanying drawings and includes all the modifications, equivalents and substitutions included in the spirit and scope of the present disclosure.

Terms including ordinal numbers such as “first,” “second” and the like, may be used to describe various components. However, these components are not limited by these terms. These terms are used only to distinguish one component from another component.

In addition, when an element such as a layer, a film, a region or a plate is referred to as being “on” or “above” another element, the element may be “directly on” another element or may have a third element interposed therebetween. On the other hand, when an element is referred to as being “directly on” another element, there is no third element interposed therebetween. In addition, when an element is referred to as being “on” or “above” a reference element, the element may be disposed on or below the reference element, and may not necessarily be “on” or “above” the reference element in an opposite direction of gravity.

It should be understood that terms “include” and “have” used in the specification specify the presence of features, numerals, steps, operations, components, parts, or combinations thereof, mentioned in this specification, and do not preclude the presence or addition of one or more other features, numerals, steps, operations, components, parts, or combinations thereof. Accordingly, unless explicitly described to the contrary, “including” any component is to be understood to imply the inclusion of other components rather than the exclusion of other components.

Further, throughout the specification, an expression “on the plane” may indicate a case where a target is viewed from the top, and an expression “on the cross-section” may indicate a case where a cross-section of a target taken along a vertical direction is viewed from its side.

Throughout the specification, when an element is referred to as being “coupled to” another element, it may not only indicate that the element and another element are “directly or physically coupled to” each other, but also indicate that the element and another element are “indirectly or contactlessly coupled to” each other while having a third element interposed therebetween.

In addition, when it is mentioned that any component is “connected to” another component, it may not only indicate that two or more components are directly connected with each other, but also indicate that two or more components are connected with each other indirectly through a third component, may not only indicate that two or more components are physically connected with each other, but also indicate that two or more components are electrically connected with each other, or two or more components are a single entity although referred to by different names based on their locations or functions.

Hereinafter, the various embodiments and modified examples of the present disclosure are described in detail with reference to the drawings.

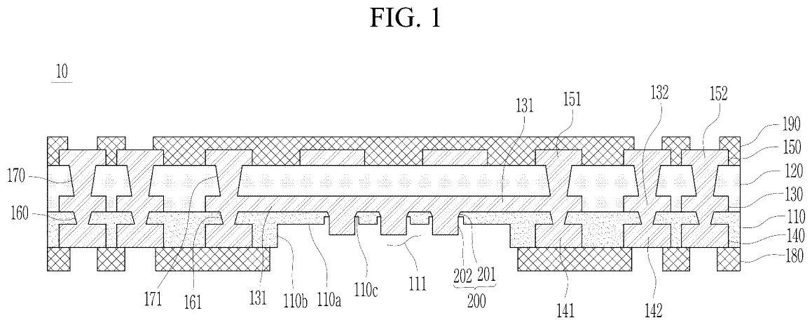

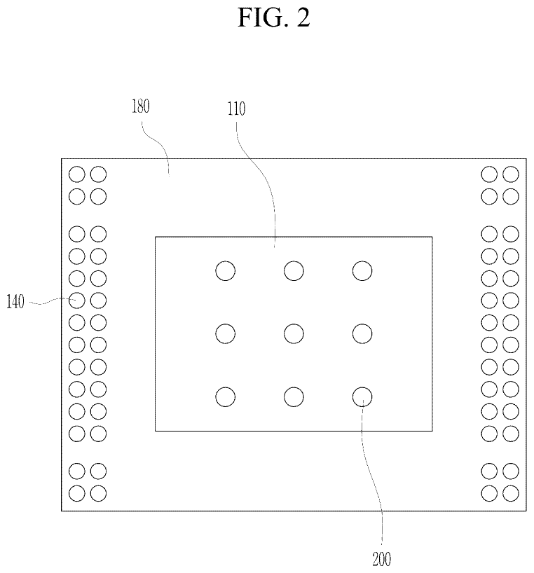

A circuit board according to an embodiment is described with reference to FIGS. 1 and 2. FIG. 1 is a cross-sectional view of the circuit board according to an embodiment, and FIG. 2 is a plan view schematically showing one surface of the circuit board of FIG. 1.

Referring to FIG. 1, a circuit board 10 according to this embodiment may include: a first insulating layer 110 having first and second surfaces opposing each other, and having a cavity 111 recessed from the first surface; a first heat dissipation pattern 131 disposed on the second surface of the first insulating layer 110; and a heat dissipation part 200 connected to the first heat dissipation pattern 131. The heat dissipation part 200 may protrude into the cavity 111 by penetrating through the first insulating layer 110.

The circuit board 10 according to this embodiment may include a plurality of insulating layers 110 and 120. The plurality of insulating layers may include the first insulating layer 110 and the second insulating layer 120 disposed on the first insulating layer 110. Each of the plurality of insulating layers may be made of an insulating material, and the insulating material may include thermosetting resin such as epoxy resin, thermoplastic resin such as polyimide, or such resin including an inorganic filler such as silica and a reinforcing material such as glass fiber. For example, each of the plurality of insulating layers may be made of prepreg or a resin coated copper (RCC) foil, but is not limited thereto, and may use a material not including the reinforcing material such as the glass fiber, for example, an Ajinomoto-build up film (ABF). When necessary, each of the plurality of insulating layers may be made of a photosensitive insulating material such as a photo image-able dielectric (PID).

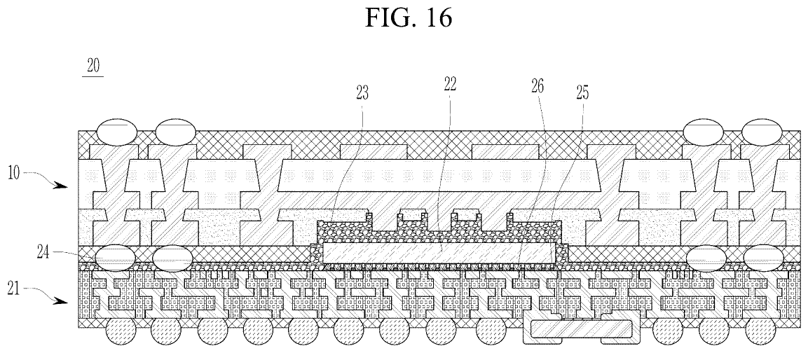

The first insulating layer 110 may have the first surface and the second surface opposing each other. The cavity 111 may be disposed in the first surface of the first insulating layer 110. The first insulating layer 110 may have the cavity 111 recessed from the first surface. The cavity 111 may be concave by being recessed from the first surface of the first insulating layer 110. The cavity 111 may be formed through an etching process. In addition, the circuit board 10 may be an interposer board connected to a board of an electronic component. In this case, a sealant 23 (see FIG. 16) may be disposed in the cavity 111.

The second insulating layer 120 may be stacked on the second surface of the first insulating layer 110 in a first direction. The first direction may refer to a direction in which the plurality of insulating layers are stacked. The second insulating layer 120 may bury at least one circuit pattern layer therein.

Referring to FIG. 1, the second insulating layer 120 is shown as one layer burying one circuit pattern layer therein, and is not limited thereto. The second insulating layer 120 may bury more circuit pattern layers therein than the number of circuit pattern layers shown in the drawing or may not bury any circuit pattern layers.

The circuit board 10 according to one embodiment may further comprise a plurality of patterned layers. Each of the plurality of patterned layers may be located on one surface of the first insulating layer 110 or the second insulating layer 120. Each of the plurality of patterned layers 130, 140, and 150 may include the heat dissipation pattern 131, 141, and 151. Each of the plurality of pattern layers 130, 140, and 150 may further include circuit pattern layers 132, 142, and 152. Each of the circuit pattern layers 132, 142, and 152 may be disposed around the respective heat dissipation pattern 131, 141, and 151.

Referring to FIG. 1, the first pattern layer 130 may include the first heat dissipation pattern 131 and the first circuit pattern layer 132 disposed around the first heat dissipation pattern 131. The second pattern layer 140 may include the second heat dissipation pattern 141 and the second circuit pattern layer 142 disposed around the second heat dissipation pattern 141. The third pattern layer 150 may include the third heat dissipation pattern 151 and the third circuit pattern layer 152 disposed around the third heat dissipation pattern 151. Referring to FIG. 1, each of the second and third pattern layers 140 and 150 is illustrated as including the heat dissipation pattern and the circuit pattern layer, but without limitation, the second and third pattern layers 140 and 150 may include any one of the heat dissipation pattern and the circuit pattern layers.

In FIG. 1, only the first to third circuit pattern layers 132, 142, and 152 are shown, but without limitation, a greater number of circuit pattern layers may be disposed than shown, or fewer circuit pattern layers may be disposed.

The circuit board 10 according to this embodiment may include a plurality of circuit pattern layers 132, 142, and 152. Each of the plurality of circuit pattern layers may be disposed on one surface of each of the insulating layers 110 and 120. The circuit pattern layers 132, 142, and 152 may transmit signals of the circuit board 10. The circuit pattern layer 132, 142, and 152 may be made of a metallic material. The metallic material may include copper (Cu), aluminum (Al), silver (Ag), tin (Sn), gold (Au), nickel (Ni), lead (Pb), titanium (Ti), an alloy thereof, or the like. The circuit pattern layer 132, 142, and 152 may perform various functions based on its design such as a ground pattern, a power pattern, or a signal pattern. Each of these patterns may have a line shape, a plane shape, or a pad shape. The circuit pattern layer disposed as the outermost layer among the plurality of circuit pattern layers 132, 142, and 152 may function as a pad for connection to another board or component.

The plurality of circuit pattern layers 132, 142, and 152 may include the first to third circuit pattern layers 130, 140, and 150.

The first circuit pattern layer 132 may be disposed on the second surface of the first insulating layer 110. The first circuit pattern layer 132 may be buried in the second insulating layer 120. As an example, the first circuit pattern layer 132 may include copper.

The second circuit pattern layer 142 may be disposed on the first surface of the first insulating layer 110. As an example, the second circuit pattern layer 142 may be buried in the first insulating layer 110. The second circuit pattern layer 142 may function as the pad for connection to another board or component. As an example, the second circuit pattern layer 142 may include copper.

The third circuit pattern layer 152 may be disposed on one surface of the second insulating layer 120. The third circuit pattern layer 152 may be disposed on a third surface of the second insulating layer 120 that opposes the second surface of the first insulating layer 110. The third circuit pattern layer 152 can function as the pad for connection to another board or component. As an example, the third circuit pattern layer 152 may include copper.

FIG. 1 shows only the first to third circuit pattern layers 132, 142, and 152. However, the present disclosure is not limited thereto, and more or fewer circuit pattern layers may be disposed than the number of circuit pattern layers shown in the drawing.

The circuit board 10 according to this embodiment may include a plurality of via layers 160 and 170. The plurality of via layers 160 and 170 may be disposed to electrically connect the first to third circuit pattern layers 132, 142, and 152 to one another. Each via electrode of the plurality of via layers 160 and 170 may have a tapered shape where a width of one surface is greater than a width of the other surface. Each of the plurality of via layers 160 and 170 may be made of the metallic material. The metal material may include copper (Cu), aluminum (Al), silver (Ag), tin (Sn), gold (Au), nickel (Ni), lead (Pb), titanium (Ti), an alloy thereof, or the like.

Each of the plurality of via layers 160 and 170 may include a signal via, a ground via, a power via, or the like, based on its design. Each via electrode of the via layers 160 and 170 may have a via hole completely filled with the metallic material, or have the metallic material formed along a wall surface of the via hole. Each of the plurality of via layers 160 and 170 may be formed through a plating process, for example, an additive process (AP), a semi AP (SAP), a Modified SAP (MSAP), or Tenting (TT). Each of the plurality of via layers 160 and 170 may include a seed layer, which is an electroless plating layer, and an electrolytic plating layer formed based on the seed layer.

The plurality of via layers 160 and 170 may include the first via layer 160 disposed in the first insulating layer 110, and the second via layer 170 disposed in the second insulating layer 120.

The first via layer 160 may penetrate through the first insulating layer 110 to be connected to the first circuit pattern layer 132 and the second circuit pattern layer 142. Therefore, through the first via layer 160, the first circuit pattern layer 132 and the second circuit pattern layer 142 may be electrically connected to each other.

The second via layer 170 may penetrate through the second insulating layer 120 to be connected to the first circuit pattern layer 132 and the third circuit pattern layer 152. Therefore, through the second via layer 170, the third circuit pattern layer 130 and the third circuit pattern layer 150 may be electrically connected to each other.

FIG. 1 shows only the first and second via layers 160 and 170, the present disclosure is not limited thereto, and more or fewer via layers may be disposed when necessary.

The circuit board 10 according to this embodiment may include the heat dissipation part 200. The heat dissipation part 200 may be connected to the first heat dissipation pattern 131. The first heat dissipation pattern 131 may be disposed on the first insulating layer 110. The heat dissipation pattern 131 may be connected to at least one circuit pattern layer. As an example, the first heat dissipation pattern 131 may be a dummy electrode or a heat dissipation electrode. In detail, the first heat dissipation pattern 131 may function to transmit heat occurring in the circuit board 10 of an embodiment rather than performing a signal transmission function. However, the present disclosure is not limited thereto, and the first heat dissipation pattern 131 may function to transmit heat occurring in the circuit board 10 while performing the signal transmission function.

Referring to FIG. 1, the first heat dissipation pattern 131 may be connected to the second heat dissipation pattern 141 through the first via layer 160. In detail, the first via layer 160 may include a first heat dissipation via electrode 161 connecting the heat dissipation pattern 131 to the second circuit pattern layer 140. The first heat dissipation via electrode 161 may function to transfer heat occurring in the circuit board 10 of an embodiment. In addition, the first heat dissipation pattern 131 may be connected to the third heat dissipation pattern 151 through the second via layer 170. In detail, the second via layer 170 may include a second heat dissipation via electrode 171 connecting the first heat dissipation pattern 131 to the third heat dissipation pattern 151. The second heat dissipation via electrode 171 may function to transfer heat occurring in the circuit board 10 of an embodiment. Heat occurring in an electronic component 22 (shown in FIG. 16) disposed in the cavity 111 may be dissipated to the top and bottom of the circuit board 10 through the first heat dissipation via electrode 161 and the second heat dissipation via electrode 171.

The second heat dissipation pattern 141 may be connected to the first heat dissipation pattern 131 via the first heat dissipation via electrode 161. Due to this connection, the second heat dissipation pattern 141 may receive heat from the first heat dissipation pattern 131 via the first heat dissipation via electrode 161, and heat generated by the electronic components 22 disposed in the cavity 111 may be transferred to one side of the circuit board 10. In this way, the heat dissipation characteristics of the circuit board 10 may be improved.

The third heat dissipation pattern 151 may be connected to the first heat dissipation pattern 131 via the second heat dissipation via electrode 171. The third heat dissipation pattern 151 may receive heat from the first heat dissipation pattern 131 via the second heat dissipation via electrode 171 and transfer heat generated by the electronic component 22 disposed in the cavity 111 to the other side of the circuit board 10, thereby improving the heat dissipation characteristics of the circuit board 10.

The first insulating layer 110 may include an upper region 110a overlapping the cavity 111 in the first direction and a side region 110b overlapping the cavity 111 in a second direction perpendicular to the first direction. The side region 110b may surround the upper region 110a. The heat dissipation part 200 may penetrate through the first insulating layer 110 to thus protrude into the cavity 111.

Referring to FIG. 2, the plurality of heat dissipation parts 200 may be provided. The plurality of heat dissipation part 200 may include portions aligned with each other in one direction. In detail, the plurality of heat dissipation parts 200 may include some heat dissipation parts aligned with each other in one direction, and other heat dissipation parts aligned with each other in another direction perpendicular to one direction. The plurality of heat dissipation parts 200 may respectively be spaced apart from each other.

The heat dissipation part 200 may be made of the metallic material. The metal material may include copper (Cu), aluminum (Al), silver (Ag), tin (Sn), gold (Au), nickel (Ni), lead (Pb), titanium (Ti), an alloy thereof, or the like.

The heat dissipation part 200 may include a first part 201 buried in the first insulating layer 110, and a second part 202 extending from the first part 201 and protruding from the upper region 110a.

The first part 201 may include a portion of the via electrode formed in the first via layer 160. The first part 201 may include a portion whose width is reduced as the first part 201 is farther away from the first heat dissipation pattern 131.

The second part 202 may protrude into the cavity 111. The second part 202 may be exposed in the upper region 110a of the first insulating layer 110, thus efficiently absorbing and dissipating heat occurring in the electronic component mounted in the cavity 111.

A length of the second part 202 protruding into the cavity 111 and a planar area of the second part 202 may be changed based on a purpose. As an example, when the electronic component accommodated in the cavity 111 has a low height, the length of the second part 202 may be made longer to improve heat dissipation efficiency. As another example, the second part 202 may have a greater planar area to thus expand a surface area of the heat dissipation part 200, thereby improving the heat dissipation efficiency.

The first insulating layer 110 may have a groove 110c in the upper region 110a. The groove 110c may be concave in the first direction. The second part 202 may be disposed in the groove 110c. The second part 202 may protrude from the groove 110c. A width of the groove 110c in the second direction may be greater than a width of the second part 202 in the second direction. In other words, an empty space may exist between the groove 110c and the second part 202, and an inner surface of the groove 110c and the second part 202 may be spaced apart from each other.

A first solder resist layer 180 may be disposed on the first surface of the first insulating layer 110 to cover a portion of the second circuit pattern layer 142, thereby preventing an unnecessary short circuit. The first solder resist layer 180 may be disposed to expose at least a portion of the second circuit pattern layer 142. The first solder resist layer 180 may include a photosensitive resin material.

A second solder resist layer 190 may be disposed on one surface of the second insulating layer 120 to cover a portion of the third circuit pattern layer 152, thereby preventing an unnecessary short circuit. The second solder resist layer 190 may be disposed to expose at least a portion of the third circuit pattern layer 152. The second solder resist layer 190 may include the photosensitive resin material.

According to the circuit board according to this embodiment, the heat dissipation part with a protruding structure may be disposed in the cavity where the electronic component is accommodated, thus efficiently absorbing and dissipating heat occurring in the electronic component while securing a mounting space of the electronic component. In addition, the length of the heat dissipation part may be adjusted, and the heat dissipation part may thus be applied to the electronic component of various thicknesses.

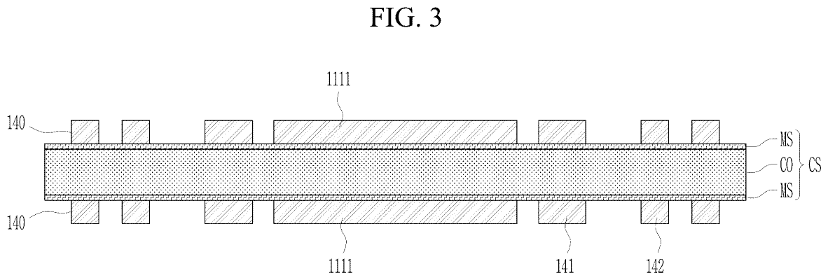

Hereinafter, a method of manufacturing the circuit board according to an embodiment is described with reference to FIGS. 3 to 15. FIGS. 3 to 15 are cross-sectional views showing the method of manufacturing the circuit board according to an embodiment.

Referring to FIG. 3, the second pattern layer 140 may be formed on a carrier board CS including a core part CO and a thin film metal layer MS stacked on each of two sides of the core part CO. The second heat dissipation pattern 141 and the second circuit pattern layer may be formed on the carrier board CS. Here, a first sacrificial layer 1111 disposed at a position where the cavity 111 is to be formed may be formed. The second circuit pattern layer 140 and the first sacrificial layer 1111 may each be formed through the plating process. The second pattern layer 140 and the first sacrificial layer 1111 may be formed by any of, but are not limited to, SAP (Semi Additive Process), MSAP (Modified Semi Additive Process), TT (Tenting), or Subtractive processes, or any process capable of forming a pattern on a circuit board. The second circuit pattern layer 142 and the first sacrificial layer 1111 may include, but are not limited to, an electroless plating layer (or chemical copper) as a seed layer and an electrolytic plating layer (or electrolytic copper) as a plating layer, respectively. As a method for forming the electroless plating layer, a sputtering layer may be used instead of a chemical copper layer. Optionally, the second pattern layer 140 may not include, or may further include, copper foil.

The first sacrificial layer 1111 may be formed together with the second pattern layer 140. The first sacrificial layer 1111 may be made of the same material as the second pattern layer 140, and have the same thickness as the second pattern layer 140. The thickness of the first sacrificial layer 1111 may correspond to a depth of the cavity 111 formed later.

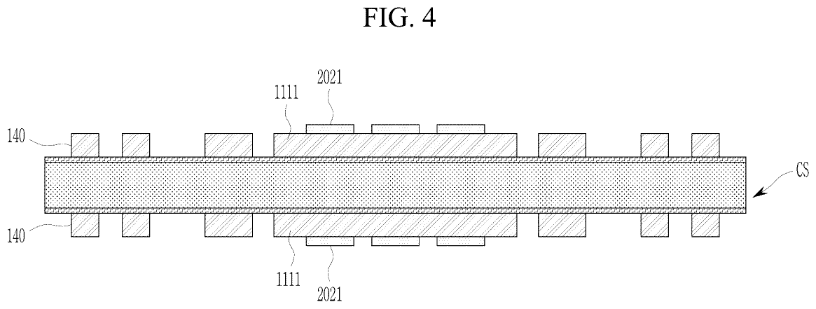

Referring to FIG. 4, a second sacrificial layer 2021 may be formed on the first sacrificial layer 1111. The second sacrificial layer 2021 may include a plurality of portions disposed on the first sacrificial layer 1111 while being spaced apart from each other. The second sacrificial layer 2021 may be formed through the plating process. For example, the second sacrificial layer 2021 may be formed by forming photoresist on the first sacrificial layer 1111, patterning the photoresist with an exposure and development process, plating to fill the patterned areas, and peeling off the photoresist. The second sacrificial layer 2021 may include nickel, and is not limited thereto.

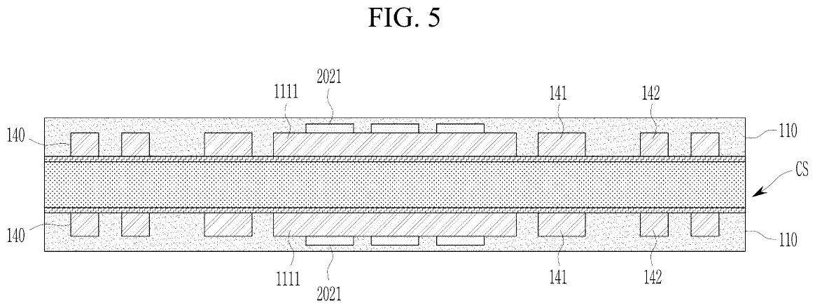

Referring to FIG. 5, the first insulating layer 110 may be formed to bury the second circuit pattern layer 142, the first sacrificial layer 1111, and the second sacrificial layer 2021 therein. The first insulating layer 110 may be made using the material such as the prepreg (PPG), the Ajinomoto-build up film (ABF), or the resin coated copper (RCC) foil.

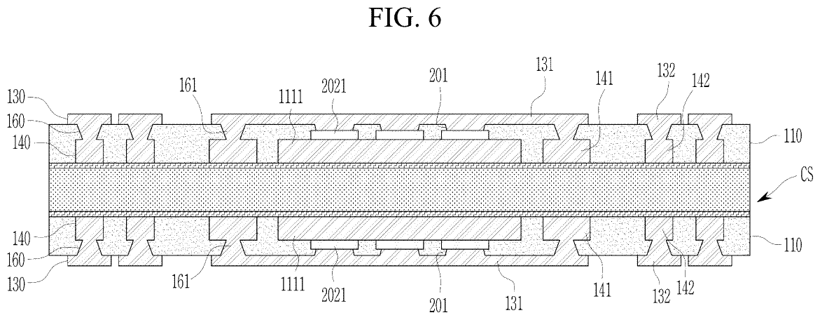

Referring to FIG. 6, the first pattern layer 130 may be formed on the first insulating layer 110, and the first via layer 160 may be formed by penetrating through at least a portion of the first insulating layer 110. Specifically, a first pattern layer 130, a first heat dissipation pattern 131, and a first circuit pattern layer 132 can be formed on the first insulating layer 110. Some via electrodes of the first via layer 160 may be formed to be in contact with the first circuit pattern layer 132 and the second circuit pattern layer 142. In other words, some via electrodes of the first via layer 160 may be formed to connect the first circuit pattern layer 132 to the second circuit pattern layer 142.

In addition, other portion of the first insulating layer 110 may be penetrated to form a first heat dissipation via electrode 161. the first heat dissipation via electrodes 161, which are some other via electrodes of the first via layer 160, may be formed to be in contact with the first heat dissipation pattern 131 the second heat dissipation pattern 141. In other words, the first heat dissipation via electrode 161 may be formed to connect the first heat dissipation pattern 131 to the second sacrificial layer 2021, and the first heat dissipation via electrode 161 may be formed to connect the first heat dissipation pattern 131 to the second heat dissipation pattern 141.

The first pattern layer 130 may be formed by any of, but is not limited to, a semi additive process (SAP), a modified semi additive process (MSAP), a tenting process (TT), or a subtractive process, or any process capable of forming a pattern on a circuit board. For example, the first pattern layer 130 may be formed by forming a seed layer by electroless plating on a copper foil, forming a photoresist on the seed layer, patterning the photoresist by an exposure and development process, filling the patterned areas with electrolytic plating, and peeling off the photoresist. The first pattern layer 130 may include, but is not limited to, an electroless plating layer (or chemical copper) as a seed layer and an electrolytic plating layer (or electrolytic copper) as a plating layer, respectively. As a method of forming the electroless plating layer, a sputtering layer may be used instead of a chemical copper layer. Optionally, the first pattern layer 130 may not include copper foil, or may further include copper foil.

The first via layer 160 may be formed by laser, mechanical drilling, or the like. In one example, the first via layer 160 can be formed by forming via through at least a portion of the first insulating layer 110 by a laser or the like, and filling the via with a conductive material to form the first via layer 160.

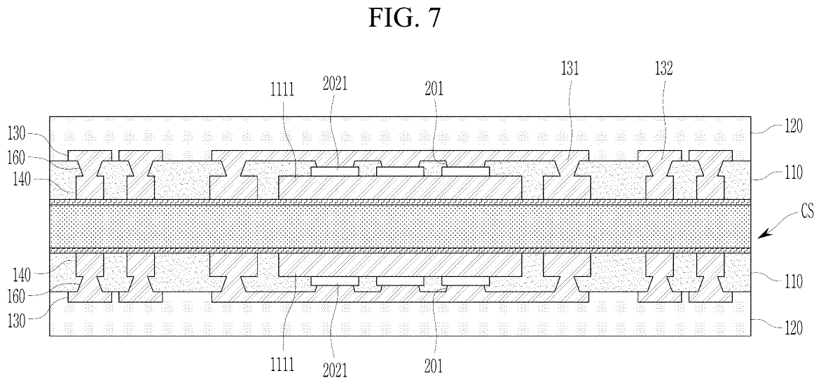

Referring to FIG. 7, the second insulating layer 120 may be formed on the first insulating layer 110 to bury the first circuit pattern layer 132 and the first heat dissipation pattern 131 therein. The second insulating layer 120 may be made using the material such as the prepreg (PPG), the Ajinomoto-build up film (ABF), or the resin coated copper foil (RCC).

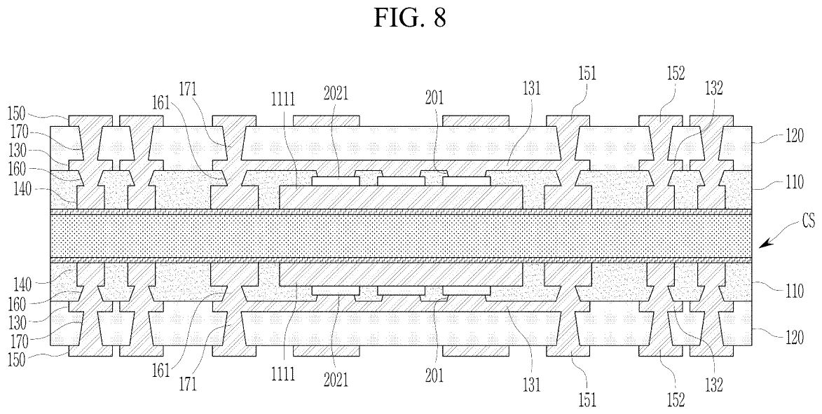

Referring to FIG. 8, the third pattern layer 150 may be formed on the second insulating layer 120, and the second via layer 170 may be formed by penetrating through at least a portion of the second insulating layer 120. Specifically, as the third pattern layer 150, a third heat dissipation pattern 151 and a third circuit pattern layer 152 can be formed on the second insulating layer 120. The some via electrode of the second via layer 170 may be formed to be in contact with the first circuit pattern layer 132 and the third circuit pattern layer 152. In other words, the some via electrode of the second via layer 170 may be formed to connect the first circuit pattern layer 132 to the third circuit pattern layer 152.

Additionally, a second heat dissipation via electrode 171 can be formed through another portion of the second insulating layer 120 to form a second heat dissipation via electrode. The second heat dissipation via electrode 171, which is another partial via electrode of the second via layer 170, can be formed to abut the first heat dissipation pattern 131 and the third heat dissipation pattern 151. In other words, the second heat dissipation via electrode 171 can be formed so that the first heat dissipation pattern 131 and the third heat dissipation pattern 151 are connected.

The third pattern layer 150 may be formed by any of, but not limited to, a semi additive process (SAP), modified semi additive process (MSAP), tenting, or subtractive process, or any process capable of forming patterns on a circuit board. For example, the third pattern layer 150 may be formed by forming a seed layer by electroless plating on a copper foil, forming a photoresist on the seed layer, patterning the photoresist by an exposure and development process, filling the patterned areas with electrolytic plating, and peeling off the photoresist. The third pattern layer 150 may include, but is not limited to, an electroless plating layer (or chemical copper) as a seed layer and an electrolytic plating layer (or electrolytic copper) as a plating layer, respectively. As a method of forming the electroless plating layer, a sputtering layer may be used instead of a chemical copper layer. Optionally, the third pattern layer may not include copper foil, or may further include copper foil.

The second via layer 170 may be formed by laser, mechanical drilling, or the like. In one example, the second via layer 170 can be formed by forming via through at least a portion of the second insulating layer 120 by a laser or the like, and filling the via with a conductive material to form the second via layer 170.

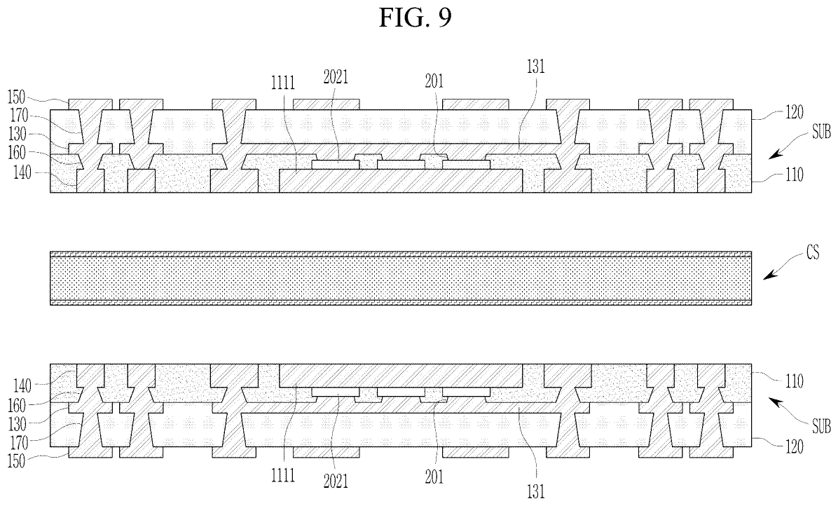

Referring to FIG. 9, a board part SUB may be separated from each of the two sides of the carrier board CS.

Hereinafter, one board unit SUB separated from the carrier board CS is described.

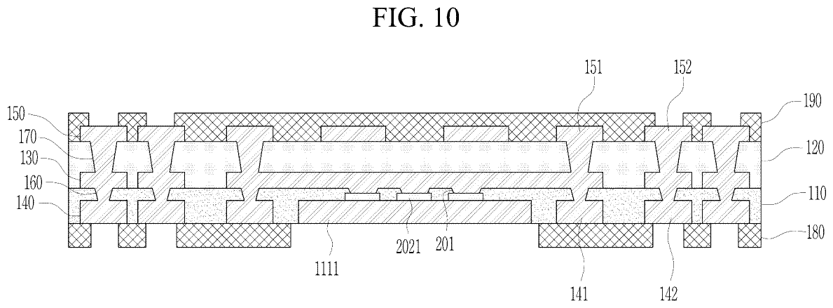

Referring to FIG. 10, the first solder resist layer 180 may be formed on the first surface of the first insulating layer 110. The first solder resist layer 180 may be formed to expose a portion of the first circuit pattern layer 130. In addition, the second solder resist layer 190 may be formed on the third surface of the second insulating layer 120. The second solder resist layer 190 may be formed to expose a portion of the third circuit pattern layer 152.

As a specific example, the first solder resist layer 180 may be formed through an exposure and development process. The first solder resist layer 180 may comprise openings that expose at least a portion of the second circuit pattern layer 142.

The second solder resist layer 190 may be formed through an exposure and development process. The second solder resist layer 190 may comprise an opening that exposes at least a portion of the third circuit pattern layer 152.

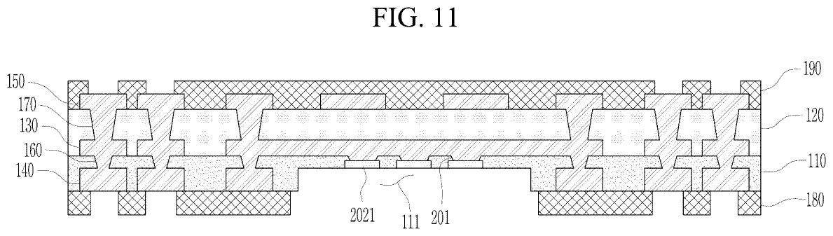

Referring to FIG. 11, the cavity 111 may be formed by etching and removing the first sacrificial layer 1111. The etching process may utilize, but is not limited to, dry etching or wet etching. In one example, an etch resist can be formed on an area other than the first sacrificial layer 1111 to be etched, and the first sacrificial layer 1111 can be removed by etching. The etch resist may include a dry film.

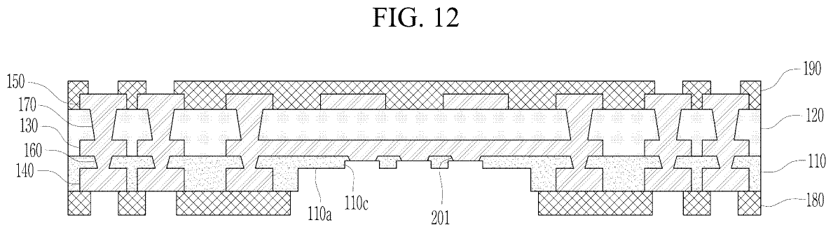

Referring to FIG. 12, the second sacrificial layer 2021 may be etched and removed to form the groove 110c in the upper region 110a of the first insulating layer 110. The etching process may utilize, but is not limited to, dry etching or wet etching. For example, the first sacrificial layer 1111 may be etched using an etchant. The second sacrificial layer 2021 may then be etched using another etchant. The first sacrificial layer 1111 and the second sacrificial layer 2021 may include the metallic materials which may be selectively removed by different etchants. As described above, for example, the first sacrificial layer 1111 may include copper, and the second sacrificial layer 2021 may include nickel. However, the present disclosure is not limited thereto. Here, one surface of the first part 201 of the heat dissipation part 200 (see FIG. 1) may be exposed to the outside through the groove 110c.

The second pattern layer 140 and the second sacrificial layer 2021 may comprise different metallic materials. Accordingly, the second pattern layer 140 and the sacrificial layer 2021 may be selectively removable by different etchants.

Furthermore, it may be possible to selectively etch the second sacrificial layer 2021 without separately masking the exposed second pattern layer 140.

In an embodiment, referring to FIGS. 10 through 12, forming the first solder resist layer 180 and the second solder resist layer 190, and etching and removing the first sacrificial layer 1111 and the second sacrificial layer 2021 have been described, but are not limited to. For example, an etch resist can be formed, the first sacrificial layer 1111 and the second sacrificial layer 2021 can be removed, and the etch resist can be removed. Thereafter, a first solder resist layer 180 can be formed on the first insulating layer 110 and a second solder resist layer 190 can be formed on the second insulating layer 120.

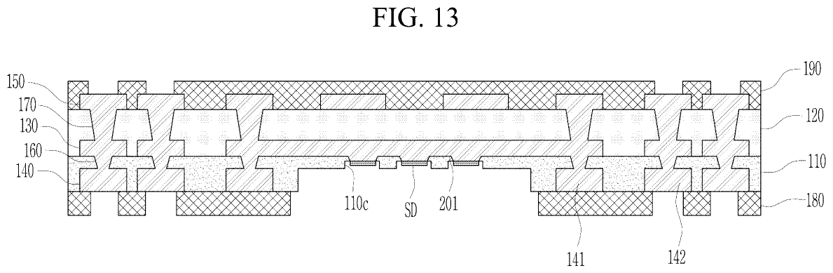

Referring to FIG. 13, a seed layer SD may be formed on one surface of the first part 201. The seed layer SD may be formed in the groove 110c. The seed layers SD may be formed by a chemical copper plating process. For example, after patterning the area to form the seed layer SD using a dry film or the like, a chemical copper plating process can be performed to form the seed layer SD.

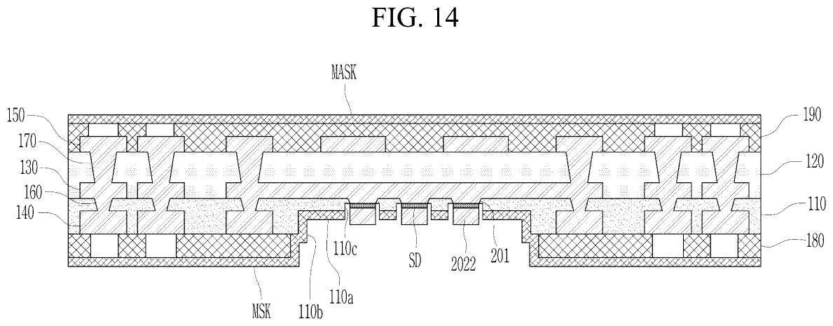

Referring to FIG. 14, a mask layer MSK may be disposed on the first solder resist layer 180, the upper region 110a of the first insulating layer 110, the side region 110b of the first insulating layer 110, and the second solder resist layer 190. In other words, the mask layer MSK may cover all the parts except for a region where the second part 202 (see FIG. 1) is to be formed. Then, a conductive part 2022 may be formed on the seed layer SD. The plurality of conductive parts 2022 may be provided. The conductive part 2022 may be formed to protrude from one surface of the first insulating layer 110. The conductive part 2022 may be formed by the plating process. The mask layer MSK may include a dry film. By forming the conductive portion 2022 on the seed layer SD, which is a chemical copper plating layer, the conductive portion 2022 can be extruded more reliably by securing the necessary adhesion force even if the area of the first surface area of the first part 201 on which the conductive portion 2022 is formed is small. However, it is possible, but not limited to, electroplating directly on the first surface of the first portion 201 to form the second portion 202 (see FIG. 1) is also possible.

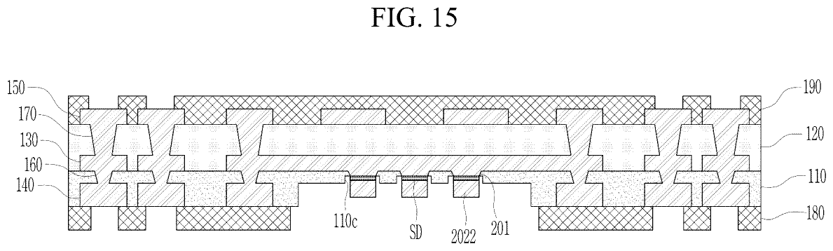

Referring to FIG. 15, the mask layer MSK may be removed to form the circuit board as shown in FIG. 1. In an embodiment, referring to FIGS. 13 through 15, forming the seed layer SD on a first side of the first portion 201 is shown, but is not limited thereto; in the seed layer forming step described with reference to FIG. 13, it is also possible to form the seed layer on a first side of the first portion 201, a first side of the second circuit pattern layer 142, and a third side of the third circuit pattern layer.

Here, a conductive portion 2022 may be formed on a portion of the seed layer disposed on the first side of the first portion 201, and the remaining portion of the seed layer may be removed to form a circuit board as in FIG. 1. The seed layer SD may be removed by the etching process. The etching process may utilize, but is not limited to, dry etching or wet etching. In one example, an etch resist may be formed on an area other than the portion of the seed layer to be etched, and the remaining portion of the seed layer SD may be removed by etching. The etch resist may include a dry film. Here, the conductive portion 2022 may have a greater thickness in the stacking direction than the portion of the seed layer SD to be etched. Thus, the conductive portion 2022 may be protected even if the conductive portion 2022 is etched along with the portion of the seed layer SD2 during the process of etching the second seed layer SD2. The first seed layer SD may be formed including a material the same as the conductive part 2022, although the present disclosure is not limited thereto. In this case, a boundary between the seed layer SD and the conductive part 2022 may not exist, as shown in FIG. 1, although the present disclosure is not limited thereto.

According to the method of manufacturing the circuit board according to this embodiment, the heat dissipation part with the protruding structure may be formed in the cavity where the electronic component is accommodated, thus efficiently absorbing and dissipating heat occurring in the electronic component while securing the mounting space of the electronic component. In addition, the length of the heat dissipation part may be adjusted during a manufacturing process, and the heat dissipation part may thus be applied to the electronic component of various thicknesses.

Hereinafter, an electronic component package according to another embodiment is described with reference to FIG. 16. FIG. 16 is a cross-sectional view schematically showing the electronic component package according to another embodiment.

Referring to FIG. 16, an electronic component package 20 according to this embodiment may include the circuit board 10 according to an embodiment described above. Hereinafter, a description of a first circuit board 10 may be applied in the same manner as the description of the circuit board 10 according to an embodiment described above.

The electronic component package 20 according to another embodiment may include: the first circuit board 10; a second circuit board 21 connected to the first circuit board 10; the electronic component 22 mounted on one surface of the second circuit board 21 and accommodated in the cavity 111; the sealant 23 disposed between the first and second circuit boards 10 and 21 to fill the cavity 111, and covering at least a portion of the electronic component 22; a conductive member 24 electrically connecting the first and second circuit boards 10 and 21 to each other; an electrode 25 electrically connecting the second circuit board 10 and the electronic component 22 to each other; and underfill 26.

The second circuit board 21 may be a circuit board on which the electronic component 22 is mounted, and include the insulating layer, a wiring layer, the via layer, and the solder resist layer.

The electronic component 22 may be a die of an integrated circuit (IC) in which hundreds to millions of elements are integrated into one chip. For example, the electronic component 22 may be a processor chip such as a central processor (CPU), a graphics processor (GPU), a field programmable gate array (FPGA), a digital signal processor, a cryptographic processor, a microprocessor, or a microcontroller. In detail, the electronic component 22 may be an application processor (AP), is not limited thereto, and may also be a memory such as a volatile memory (e.g., the DRAM), a non-volatile memory (e.g., a read-only memory (ROM)), a flash memory, or logic such as an analog-to-digital converter or an application-specific IC (ASIC). When necessary, the electronic component 22 may be a passive component in the form of a chip, for example, a chip-type capacitor such as a multi-layer ceramic capacitor (MLCC) or a chip-type inductor such as a power inductor (PI). The electronic component 22 may be covered by the sealant 23, and have at least one surface in physical contact with the sealant 23.

The sealant 23 may cover one surface of the first solder resist layer 180, one surface of the second circuit board 21, and at least a portion of an outer surface of the electronic component 22. In addition, the sealant 23 may fill at least a portion of the cavity 111 and, as a result, the sealant 23 may cover at least a portion of an upper surface of the electronic component 22. For example, the sealant 23 may be in physical contact with at least a portion of each of the upper, lower, and side surfaces of the electronic component 22. The sealant 23 may have fluidity in a pre-cured state, and thus flow along the outer surface of the electronic component 22 and the surface of the first insulating layer 110, thereby filling the inside of the cavity 111.

The sealant 23 may be made of an insulating material, and the insulating material may use the thermosetting resin such as epoxy resin or the thermoplastic resin such as polyimide. In addition, the sealant 23 may use such resin including the inorganic filler such as silica. For example, the sealant 23 may be made of the Ajinomoto-build up film (ABF). The ABF may be provided in a form of the resin coated copper foil (RCC), and the sealant 23 is not limited thereto. When necessary, the sealant 23 may be made of the photosensitive material such as the photo image-able dielectric (PID). In addition, the sealant 23 may be a known epoxy molding compound (EMC), and is not limited thereto.

The conductive member 24 may be disposed in at least a portion of an opening of the second circuit board 21. The conductive member 24 may physically and/or electrically connect the second circuit board 21 to the outside. For example, the conductive member 24 may electrically connect the exposed circuit pattern layer of the second circuit board 21 and the second circuit pattern layer 142 of the first circuit board 10. The conductive member 24 may be made of tin (Sn) or an alloy including tin (Sn), for example, a solder, and is not limited thereto. For example, the conductive member 24 may have a metal post having a shape of a ball, a land, a pin, or a pillar, or a shape of a pillar to which the plurality of balls are coupled.

The underfill 26 may be a material filling a space between the electronic component 22 mounted in the cavity 111 of the second circuit board 21 and the second circuit board 21, and fix the electronic component 22 in the cavity 111. In particular, the underfill 26 may fill the inside of a gap when the electrode 25 protrudes and the gap thus occurs between one surface of the electronic component 22 and the second circuit board 21.

According to the electronic component package according to this embodiment, the heat dissipation part with the protruding structure is disposed in the cavity of the first circuit board where the electronic component is accommodated, thus efficiently absorbing and dissipating heat occurring in the electronic component while securing the mounting space of the electronic component. In addition, the length of the heat dissipation part may be adjusted, and the heat dissipation part may thus be applied to the electronic component of various thicknesses.

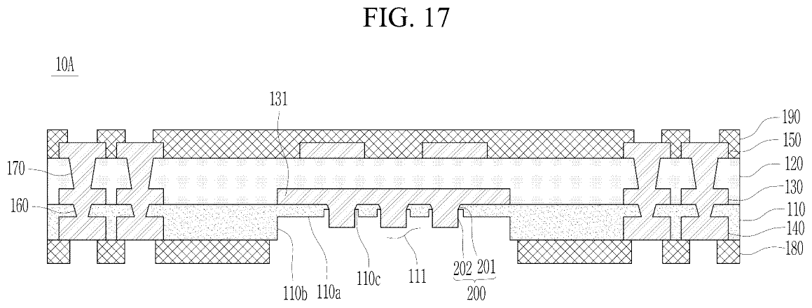

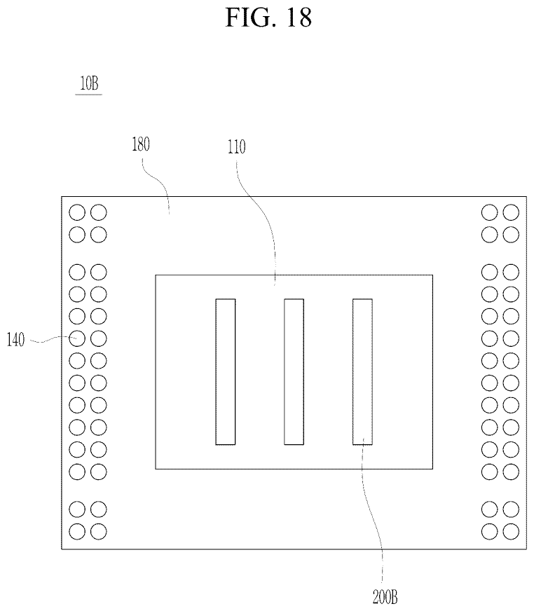

FIGS. 17 and 18 are views respectively describing circuit boards in various examples. FIG. 17 is a cross-sectional view of a circuit board in another example; and FIG. 18 is a plan view schematically showing one surface of a circuit board in still another example.

Referring to FIG. 17, a circuit board 10A in other example is similar to the circuit board according to an embodiment described with reference to FIGS. 1 and 2. The description omits a detailed description of the same component.

Referring to FIG. 17, unlike the circuit board according to an embodiment shown in FIG. 1, in the circuit board 10A in other example, the via layer 160 may not include the first heat dissipation via electrode 161, and the second via layer 170 may not include the second heat dissipation via electrode 171. In other words, the first heat dissipation pattern 131 may not be connected to another circuit pattern layer. As described above, each of the heat dissipation pattern and the heat dissipation part may have a simple structure, and the heat dissipation part may thus be formed on the circuit board to thus efficiently absorb and dissipate heat even when it is difficult to connect the circuit pattern layer to the heat dissipation pattern due to a complex design of the circuit pattern layer.

Referring to FIG. 18, a circuit board 10B in another example is similar to the circuit board according to an embodiment described with reference to FIGS. 1 and 2. The description omits a detailed description of the same component.

Referring to FIG. 18, unlike the circuit board according to an embodiment shown in FIG. 1, in the circuit board 10B in another example, a heat dissipation part 200B may extend to be parallel to an edge of the cavity 111. The heat dissipation part 200B may extend in one direction perpendicular to the first direction. For example, the heat dissipation part 200B may extend in the second direction. The heat dissipation part 200B may have a rectangular planar shape or have a stripe shape in a plan view, and is not limited thereto. As an example, the heat dissipation part 200B may be formed by forming a via with a laser or the like in a via overlapping method. As described above, the heat dissipation part may have the wider planar area to thus expand the surface area of the heat dissipation part that is exposed in the cavity where the electronic component is accommodated, thereby improving the heat dissipation efficiency.

Although the embodiments of the present disclosure have been described, it is to be understood that the present disclosure is not limited to the disclosed embodiments. Various modifications may be made within the scopes disclosed in the claims, detailed description, and accompanying drawings of the present disclosure, and these modifications also fall within the scope of the present disclosure.

What is claimed is:

1. A circuit board comprising:
a first insulating layer having first and second surfaces opposing each other, and having a cavity recessed from the first surface;
a first heat dissipation pattern disposed on the second surface of the first insulating layer; and
a heat dissipation part connected to the first heat dissipation pattern, and protruding into the cavity by penetrating through the first insulating layer.

2. The circuit board of claim 1, further comprising
a second insulating layer disposed on the second surface in a first direction to cover the first heat dissipation pattern and at least one circuit pattern layer,
wherein the first insulating layer includes an upper region overlapping the cavity in the first direction and a side region overlapping the cavity in a second direction perpendicular to the first direction, and
the heat dissipation part protrudes from the upper region.

3. The circuit board of claim 2, wherein
the heat dissipation part includes:
a first part buried in the first insulating layer, and
a second part extending from the first part and protruding from the upper region.

4. The circuit board of claim 3, wherein
the first insulating layer has a groove in the upper region where the second part is disposed, and
the groove surrounds the second part.

5. The circuit board of claim 1, further comprising:
a first pattern layer including the first heat dissipation pattern and a first circuit pattern layer disposed around the first heat dissipation pattern,
wherein the first heat dissipation pattern is connected to at least one other pattern layer.

6. The circuit board of claim 5, further comprising:
a second heat dissipation pattern disposed on the first surface of the first insulating layer,
Wherein the first heat dissipation pattern is connected to the second heat dissipation pattern.

7. The circuit board of claim 5, further comprising:
a second insulating layer disposed on the second surface in a first direction to cover at least one pattern layer including the first pattern layer; and
a third heat dissipation pattern disposed on a third surface of the second insulating layer that opposes the second surface of the first insulating layer,
wherein the first heat dissipation pattern is connected to the third heat dissipation pattern.

8. The circuit board of claim 1, wherein
the heat dissipation part extends to be parallel to an edge of the cavity.

9. The circuit board of claim 1, wherein
the plurality of heat dissipation parts are provided, and
the plurality of heat dissipation parts include portions aligned with each other in one direction.

10. The circuit board of claim 1, wherein
the plurality of heat dissipation parts are provided, and
the plurality of heat dissipation parts are spaced apart from each other.

11. The circuit board of claim 1, wherein
the heat dissipation part includes copper.

12. An electronic component package comprising:
a first circuit board having a cavity in one surface;
a second circuit board connected to the first circuit board; and
an electronic component mounted on one surface of the second circuit board, and accommodated in the cavity,
wherein the first the circuit board includes:
a first insulating layer having first and second surfaces opposing each other, and having the cavity recessed from the first surface,
a first heat dissipation pattern disposed on the second surface of the first insulating layer, and
a heat dissipation part connected to the first heat dissipation pattern, and protruding into the cavity by penetrating through the first insulating layer.

13. The package of claim 12, further comprising:
a second insulating layer disposed on the second surface in a first direction to cover the first heat dissipation pattern and at least one circuit pattern layer,
wherein the first insulating layer includes an upper region overlapping the cavity in the first direction and a side region overlapping the cavity in a second direction perpendicular to the first direction, and
the heat dissipation part protrudes from the upper region.

14. The package of claim 13, wherein
the heat dissipation part includes:
a first part buried in the first insulating layer, and
a second part extending from the first part and protruding from the upper region.

15. The package of claim 14, wherein
the first insulating layer has a groove in the upper region where the second part is disposed, and
a width of the groove is greater than a width of the second part.

16. The package of claim 12, further comprising:
a first pattern layer including the first heat dissipation pattern and a first circuit pattern layer disposed around the first heat dissipation pattern,
wherein the first heat dissipation pattern is connected to at least one other pattern layer.

17. The package of claim 16, further comprising:
a second heat dissipation pattern disposed on the first surface of the first insulating layer,
wherein the first heat dissipation pattern is connected to the second heat dissipation pattern.

18. The package of claim 16, further comprising:
a second insulating layer disposed on the second surface in a first direction to cover at least one pattern layer including the first pattern layer; and
a third heat dissipation pattern disposed on a third surface of the second insulating layer that opposes the second surface of the first insulating layer,
wherein the first heat dissipation pattern is connected to the third heat dissipation pattern.

19. The package of claim 12, wherein
the heat dissipation part extends to be parallel to an edge of the cavity.

20. The package of claim 12, wherein
the plurality of heat dissipation parts are provided, and
the plurality of heat dissipation parts include portions aligned with each other in one direction.
